(19) United States
(12) Patent Application Publication
(10) Pub. No.: US 2025/0125236 A1
(43) Pub. Date: Apr. 17, 2025

(54) SEMICONDUCTOR PACKAGE

(71) Applicant: SAMUNG ELECTRONICS CO., LTD., Suwon-si (KR)

(72) Inventors: Hyungmin KIM, Suwon-si (KR); Eunseok CHO, Suwon-si (KR); Jaehoon CHOI, Suwon-si (KR)

(73) Assignee: SAMUNG ELECTRONICS CO., LTD., Suwon-si (KR)

(21) Appl. No.: 18/912,330

(22) Filed: Oct. 10, 2024

(30) Foreign Application Priority Data
Oct. 11, 2023 (KR) 10-2023-0135398

(51) Int. Cl. H01L 23/498; H01L 23/31; H01L 25/10

(52) U.S. Cl. CPC H01L 23/49816; H01L 23/49833; H01L 25/105; H01L 23/3107; H01L 2225/1041; H01L 2225/1058

(57) ABSTRACT

A semiconductor package includes: a first substrate having a rectangular cross-section on an X-Y plane, wherein the first substrate includes an upper surface and a lower surface opposite to the upper surface, and an aspect ratio of the rectangular cross-section is in a range of 1.5 to 2.2; a first chip on the upper surface of the first substrate; and a plurality of dummy balls on each of four corner areas of the lower surface of the first substrate.

### CROSS-REFERENCE TO RELATED APPLICATION

This application is based on and claims priority under 35 U.S.C. § 119 to Korean Patent Application No. 10-2023-0135398, filed on Oct. 11, 2023, in the Korean Intellectual Property Office, the disclosure of which is incorporated by reference herein in its entirety.

### BACKGROUND

The present disclosure relates to a semiconductor package, and more specifically, to a semiconductor package including a dummy ball.

As the storage capacity of semiconductor devices increases, there is a need for semiconductor packages including semiconductor devices that are thinner and lighter. Recently, research on improving the operating speed of a plurality of semiconductor chips and improving the structural reliability of semiconductor packages has been actively conducted. In order to minimize defects in miniaturized semiconductor packages, issues regarding the placement of dummy balls are emerging.

### SUMMARY

One or more example embodiments provide a semiconductor package with improved reliability by optimizing the arrangement of dummy balls provided on a lower surface of a substrate having a rectangular cross-section on an X-Y plane.

According to an aspect of an example embodiment, a semiconductor package includes: a first substrate having a rectangular cross-section on an X-Y plane, wherein the first substrate includes an upper surface and a lower surface opposite to the upper surface, and an aspect ratio of the rectangular cross-section is in a range of 1.5 to 2.2; a first chip on the upper surface of the first substrate; and a plurality of dummy balls on each of four corner areas of the lower surface of the first substrate.

According to an aspect of an example embodiment, a semiconductor package including: a first substrate having a rectangular cross-section on an X-Y plane, wherein the first substrate includes an upper surface and a lower surface opposite to the upper surface, and an aspect ratio of the rectangular cross-section is in a range of 1.5 to 2.2; a first chip on the upper surface of the first substrate; a second chip on the upper surface of the first substrate and spaced apart from the first chip in a Y-axis direction; and a plurality of dummy balls on each of four corner areas of the lower surface of the first substrate, wherein a footprint of the first substrate is greater than a sum of a footprint of the first chip and a footprint of the second chip.

According to an aspect of an example embodiment, a semiconductor package including: a first substrate having a rectangular cross-section along an X-Y plane, wherein the first substrate includes an upper surface and a lower surface opposite to the upper surface, and an aspect ratio of the rectangular cross-section is in a range of 1.5 to 2.2; a first chip on the upper surface of the first substrate; a second chip on the upper surface of the first substrate and spaced apart from the first chip in a Y-axis direction; a plurality of dummy balls on each of four corner areas of the lower surface of the first substrate; and a plurality of first bumps on the lower surface of the first substrate, wherein a length of a shorter side of the rectangular cross-section is in a range of 8 mm to 12 mm, a number of the plurality of dummy balls on each of the four corner areas is in a range of 8 to 16, each of the plurality of dummy balls is electrically disconnected from a wiring provided in the first substrate, and the plurality of dummy balls have different arrangements in at least two corner areas from among the four corner areas.

### BRIEF DESCRIPTION OF THE DRAWINGS

The above and other aspects and features will be more apparent from the following detailed description of example embodiments taken in conjunction with the accompanying drawings, in which:

FIG. 1 is a schematic cross-sectional view of a semiconductor package on a Y-Z plane, according to one or more example embodiments;

FIG. 2 is a schematic cross-sectional view taken along line A1-A1′ of the semiconductor package of FIG. 1, according to one or more example embodiments;

FIG. 3 is a schematic cross-sectional view taken along line A1-A1′ of the semiconductor package of FIG. 1, according to one or more example embodiments;

FIG. 4 is a schematic cross-sectional view taken along line A1-A1′ of the semiconductor package of FIG. 1, according to one or more example embodiments;

FIG. 5 is a schematic cross-sectional view taken along line A1-A1′ of the semiconductor package of FIG. 1 according to one or more example embodiments;

FIG. 6 is a schematic cross-sectional view taken along line A1-A1′ of the semiconductor package of FIG. 1, according to one or more example embodiments;

FIG. 7 is a schematic cross-sectional view taken along line A1-A1′ of the semiconductor package of FIG. 1, according to one or more example embodiments;

FIG. 8 is a schematic cross-sectional view of a semiconductor package on a Y-Z plane, according to one or more example embodiments;

FIG. 9 is a schematic cross-sectional view of the semiconductor package of FIG. 8 on a Y-Z plane, according to one or more example embodiments;

FIG. 10 is a schematic cross-sectional view of the semiconductor package of FIG. 8 on a Y-Z plane, according to one or more example embodiments;

FIG. 11 is a schematic cross-sectional view of a semiconductor package on a Y-Z plane, according to one or more example embodiments;

FIG. 12 is a schematic cross-sectional view of a semiconductor package on a Y-Z plane, according to one or more example embodiments;

FIG. 13 is a schematic plan view of the semiconductor package of FIG. 12, according to one or more example embodiments; and

FIG. 14 is a schematic cross-sectional view taken along line B1-B1′ of the semiconductor package of FIG. 12, according to one or more example embodiments.

### DETAILED DESCRIPTION

Hereafter, example embodiments will be described in detail with reference to the accompanying drawings. In describing the drawings, like reference numerals are used for elements that are substantially identical or correspond to each other, and duplicate descriptions thereof are omitted.

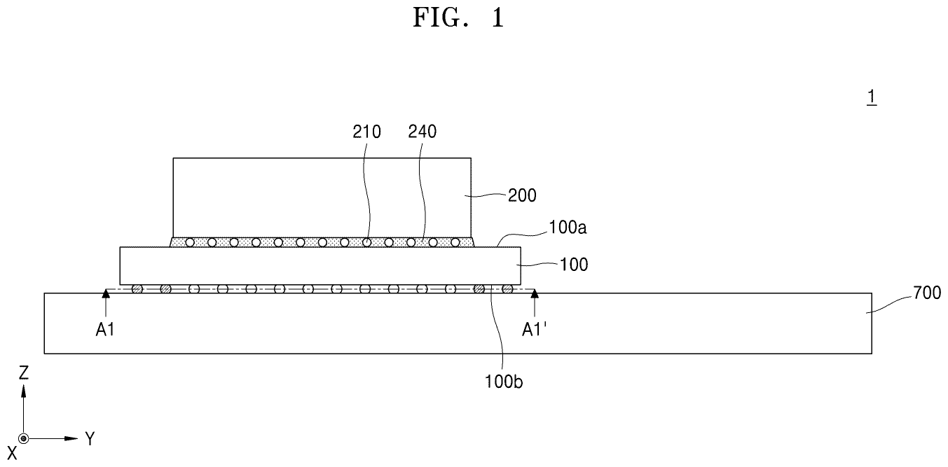

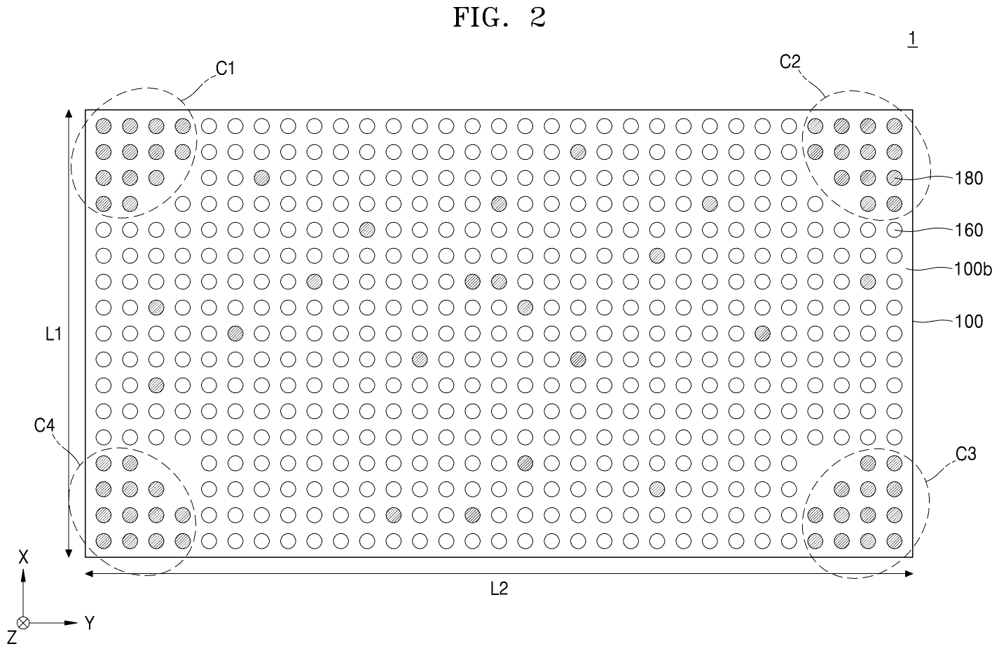

FIG. 1 is a schematic cross-sectional view of a semiconductor package 1 on a Y-Z plane, according to one or more example embodiments. FIG. 2 is a schematic cross-sectional view taken along line A1-A1′ of the semiconductor package 1 of FIG. 1, according to one or more example embodiments.

Referring to FIGS. 1 and 2, the semiconductor package 1 may include a first substrate 100, a first chip 200, and a second substrate 700. The first substrate 100 may be located below the first chip 200 and may have an upper surface 100a and a lower surface 100b opposite to the upper surface 100a. Hereinafter, in the drawings, according to one or more example embodiments, an X-axis direction and a Y-axis direction may represent directions parallel to the upper surface 100a or the lower surface 100b of the first substrate 100, and the X-axis direction and the Y-axis direction may be perpendicular to each other. According to one or more example embodiments, a Z-axis direction may represent a direction perpendicular to the upper surface 100a or the lower surface 100b of the first substrate 100. In other words, the Z-axis direction may be perpendicular to an X-Y plane. Also, in the drawings, according to one or more example embodiments, a first horizontal direction may represent the X-axis direction, a second horizontal direction may represent the Y-axis direction, and the vertical direction may represent the Z-axis direction.

The first substrate 100 may be a substrate on which the first chip 200 is mounted. In one or more example embodiments, the first substrate 100 may be provided using a ceramic substrate, a printed circuit board (PCB), an organic substrate, etc. For example, the first substrate 100 may include an insulating layer including at least one material selected from among Frame Retardant 4 (FR-4), tetrafunctional epoxy, polyphenylene ether, epoxy/polyphenylene oxide, bismaleimide triazine (BT), thermount, cyanate ester, polyimide, and liquid crystal polymer. The first substrate 100 may include a pattern located within the insulating layer and including copper, nickel, stainless steel, or beryllium copper. In one or more example embodiments, the first substrate 100 may be a redistribution substrate formed using a redistribution process. For example, the first substrate 100 may include a redistribution insulating layer including a photo imageable dielectric (PID) or photosensitive polyimide (PSPI), and a redistribution pattern located within the redistribution insulating layer and including copper (Cu) or aluminum. (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), ruthenium (Ru), etc. However, the type of the first substrate 100 is not limited to the aforementioned one or more example embodiments, and one or more example embodiments may include any substrate that may be electrically connected to the first chip 200.

The first substrate 100 may have a rectangular shaped cross-section on the X-Y plane. According to one or more example embodiments, a ratio of a first length L1, which is a length of a short side of a rectangle that is a cross-section on the X-Y plane of the first substrate 100, relative to a second length L2, which is a length of a long side of the rectangle, may be 1.5 or more. In one or more example embodiments, the ratio of the first length L1 relative to the second length L2 of the rectangular cross-section on the X-Y plane of the first substrate 100 may be in a range of about 1.5 to about 2.2. According to one or more example embodiments, the ratio of the first length L1 to the second length L2 of the rectangle, which is a cross-section on the X-Y plane of the first substrate 100, may mean the same as an aspect ratio of a rectangle, which is a cross-section on the X-Y plane of the first substrate 100. In one or more example embodiments, the first length L1 of a rectangle, which is a cross-section on the X-Y plane of the first substrate 100, may be in a range of about 8 mm to about 12 mm.

The first chip 200 may be provided on the upper surface 100a of the first substrate 100. The first chip 200 may include a semiconductor chip. The semiconductor chip may include a memory chip or a logic chip. The memory chip may include, for example, a volatile memory chip, such as dynamic random access memory (DRAM) or static random access memory (SRAM), or a non-volatile memory chip, such as phase-change random access memory (PRAM), magnetoresistive random access memory (MRAM), ferroelectric random access memory (FeRAM), or resistive random access memory (RRAM). The logic chip may comprise, for example, a microprocessor, such as a central processing unit (CPU), a graphics processing unit (GPU), or an application processor (AP), an analog element, or a digital signal processor.

According to one or more example embodiments, the first chip 200 may be mounted on the upper surface 100a of the first substrate 100 using a flip chip method. For example, the first chip 200 may be mounted on the upper surface 100a of the first substrate 100 using a flip chip method using first chip connection bumps 210, such as micro bumps. According to one or more example embodiments, a first underfill material layer 240 surrounding the first chip connection bumps 210 may be provided between the first chip 200 and the first substrate 100. The first underfill material layer 240 may include, for example, an epoxy resin formed using a capillary under-fill method. However, in one or more example embodiments, a molding member may be directly filled into a gap between the first chip 200 and the first substrate 100 through a molded under-fill process. According to one or more example embodiments, the first underfill material layer 240 may be omitted. However, the method of mounting the first chip 200 on the upper surface 100a of the first substrate 100 is not limited to the aforementioned one or more example embodiments, and the first chip 200 may be mounted on the upper surface 100a of the substrate 100 using wire bonding, direct bonding, etc.

According to one or more example embodiments, a footprint of the first substrate 100 may be greater than a footprint of the first chip 200. The first chip 200 may entirely overlap the first substrate 100 in the vertical direction (Z).

The second substrate 700 may be located below the first substrate 100 and may be electrically connected to the first substrate 100. According to one or more example embodiments, the second substrate 700 may include a motherboard. For example, a plurality of first substrates 100 on which at least one semiconductor chip is mounted may be provided on an upper surface of the second substrate 700.

A first bump 160 and a dummy ball 180 may be provided on the lower surface 100b of the first substrate 100. The first substrate 100 may be mounted on the second substrate 700 using the first bump 160. The first substrate 100 may be electrically connected to the second substrate 700 using the first bump 160. The dummy ball 180 may not be electrically connected to the first substrate 100. For example, the first bump 160 may be electrically connected to a wiring provided in the first substrate 100, and the dummy ball 180 may not be electrically connected to the wiring provided in the first substrate 100. In one or more example embodiments, the dummy ball 180 and the first bump 160 may include substantially the same material and may be provided in the same shape. According to one or more example embodiments, a plurality of first bumps 160 and dummy balls 180 may be provided.

The lower surface 100b of the first substrate 100 may have a rectangular shape as shown in FIG. 2. The lower surface 100b of the first substrate 100 may include four corners C1, C2, C3, and C4. The four corners C1, C2, C3, and C4 of the lower surface 100b of the first substrate 100 may be represented as a second corner C2, a third corner C3, and a fourth corner C4 in a clockwise direction relative to a first corner C1 at the upper left corner, as shown in FIG. 2.

The plurality of dummy balls 180 may be provided on corner areas respectively corresponding to the first, second, third and fourth corners C1, C2, C3, and C4 of the lower surface 100b of the first substrate 100. Herein, the terms “corner” and “corner area” may be used interchangeably. The dummy balls 180 may have a shape extending downward in the vertical direction (Z) from the lower surface 100b of the first substrate 100. According to one or more example embodiments, the plurality of dummy balls 180 provided at each of the first, second, third and fourth corners C1, C2, C3, and C4 may be in the same number and arrangement. For example, the arrangement of the dummy balls 180 located at the first corner C1 may be the same as the arrangement of the dummy balls 180 located at each of the second corner C2, the third corner C3, and the fourth corner C4, and the number of dummy balls 180 provided at the first corner C1 may be the same as the number of dummy balls 180 provided at each of the second corner C2, the third corner C3, and the fourth corner C4.

The arrangement of the plurality of dummy balls 180 located at each of the first, second, third and fourth corners C1, C2, C3, and C4 is not limited to that shown in FIG. 2 according to one or more example embodiments, and the plurality of dummy balls 180 may be arranged in various ways at each of the first, second, third and fourth corners C1, C2, C3, and C4, respectively.

According to one or more example embodiments, the number of dummy balls 180 provided at each of the first, second, third and fourth corners C1, C2, C3, and C4 may be eight or more. For example, eight or more dummy balls 180 may be provided at each of the first, second, third and fourth corners C1, C2, C3, and C4. According to one or more example embodiments, the number of dummy balls 180 provided at each of the first, second, third and fourth corners C1, C2, C3, and C4 may range from 8 to 16. According to one or more example embodiments, the dummy balls 180 may be provided in an area other than the first, second, third and fourth corners C1, C2, C3, and C4 of the lower surface 100b of the first substrate 100. For example, the dummy balls 180 may also be provided at a center portion of the lower surface 100b of the first substrate 100. According to one or more example embodiments, the dummy balls 180 provided at the center of the lower surface 100b of the first substrate 100 may physically fix the first substrate 100 and the second substrate 700.

In the related art, in order to efficiently distribute stress caused by a load of the semiconductor package 1 itself, external force applied to the semiconductor package 1, or differences in heat strain between components of the semiconductor package 1, the dummy balls 180 are provided at each of the first, second, third and fourth corners C1, C2, C3, and C4 of the first substrate 100, where a lot of stress is generated. The first substrate 100 may have a square shape or a rectangular shape with an aspect ratio of 1.2 or less on the X-Y plane. Accordingly, relatively the same level of stress is caused in the first, second, third and fourth corners C1, C2, C3, and C4 of the first substrate 100.

However, the semiconductor package 1 according to one or more example embodiments may include the first substrate 100 having a rectangular cross-section on the X-Y plane and an aspect ratio of 1.5 or more. Accordingly, at the first, second, third and fourth corners C1, C2, C3, and C4 of the first substrate 100, a relatively different amount of stress may occur compared to when the first substrate 100 has a square cross-section on the X-Y plane, or a rectangular cross-section with an aspect ratio of 1.2 or less.

In addition, stress may be generated unevenly on the lower surface 100b of the first substrate 100 due to the first substrate 100 having a rectangular cross-section on the X-Y plane with an aspect ratio of 1.5 or more. For example, greater stress may occur on a short side of the lower surface 100b of the first substrate 100.

Because the semiconductor package 1 according to one or more example embodiments includes a plurality of dummy balls 180 at each of the first, second, third and fourth corners C1, C2, C3, and C4 that receive the greatest stress on the lower surface 100b of the first substrate 100, and a greater number of dummy balls 180 are provided at each of the first, second, third and fourth corners C1, C2, C3, and C4 than in the case when the first substrate 100 has a square cross-section on the X-Y plane or a rectangle with an aspect ratio of 1.2 or less, stress applied to the lower surface 100b of the first substrate 100 may be more efficiently distributed toward the dummy balls 180.

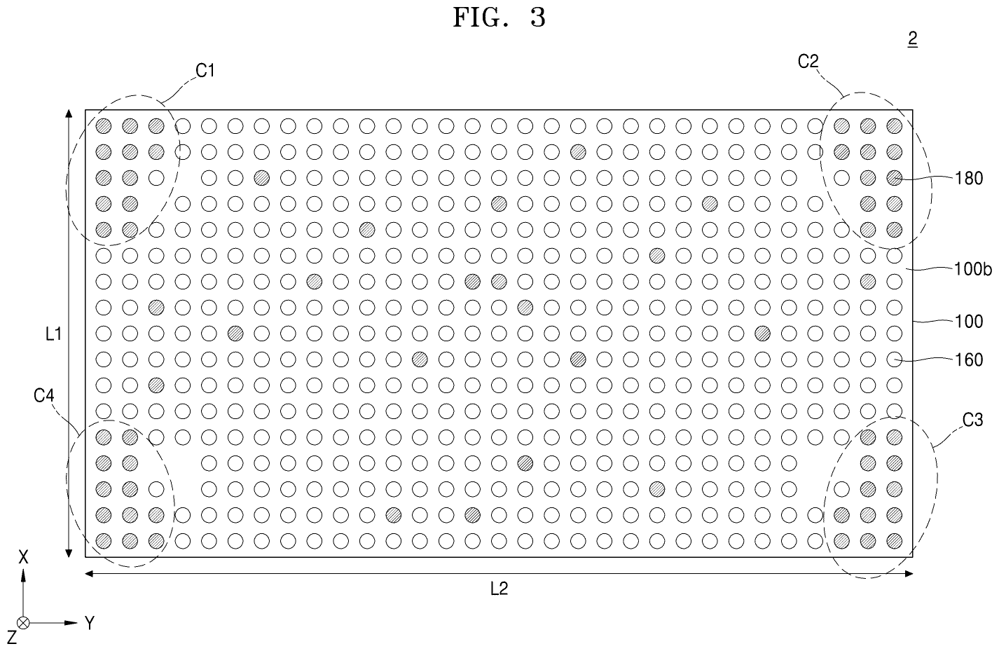

FIG. 3 is a schematic cross-sectional view taken along line A1-A1′ of the semiconductor package 1 of FIG. 1. Hereinafter, in describing a semiconductor package 2 of FIG. 3, according to one or more example embodiments, duplicate descriptions previously given with respect to the semiconductor package 1 with reference to one or more example embodiments shown in FIG. 1 are omitted, and mainly the differences will be explained.

Referring to FIG. 3, according to one or more example embodiments, the semiconductor package 2 may include a first bump 160 and a dummy ball 180 provided on the lower surface 100b of the first substrate 100. A plurality of first bumps 160 and dummy balls 180 may be provided on the semiconductor package 2.

A plurality of dummy balls 180 may be provided at each of the four corners C1, C2, C3, and C4 of the lower surface 100b of the first substrate 100. The four corners C1, C2, C3, and C4 of the lower surface 100b of the first substrate 100 may be represented as a second corner C2, a third corner C3, and a fourth corner C4 in a clockwise direction relative to a first corner C1 at the upper left corner, as shown in FIG. 3.

According to one or more example embodiments, the number and arrangement of dummy balls 180 provided at each of the first, second, third and fourth corners C1, C2, C3, and C4 may be substantially the same. For example, the arrangement of the dummy balls 180 located at the first corner C1 may be the same as the arrangement of the dummy balls 180 located at each of the second corner C2, the third corner C3, and the fourth corner C4, and the number of dummy balls 180 provided at the first corner C1 may be the same as the number of dummy balls 180 provided at each of the second corner C2, the third corner C3, and the fourth corner C4.

According to one or more example embodiments, the number of dummy balls 180 provided at each of the first, second, third and fourth corners C1, C2, C3, and C4 is more on a short side of the lower surface 100b of the first substrate 100 than on a long side of the lower surface 100b. For example, among the dummy balls 180 provided at each of the first, second, third and fourth corners C1, C2, C3, and C4, the number of dummy balls 180 provided facing the short side of the lower surface 100b of the first substrate 100 may be more than the number of dummy balls 180 provided facing the long side of the lower surface 100b of the substrate 100. Accordingly, when a virtual figure is created with a bundle of dummy balls 180 provided at each of the first, second, third and fourth corners C1, C2, C3, and C4, the virtual figure may have a shape extending in a direction parallel to the short side of the lower surface 100b of the first substrate 100. That is, the virtual figure may have an elongated shape in a direction in which the short side of the lower surface 100b of the first substrate 100 extends.

The first substrate 100 has a rectangular cross-section on the X-Y plane with an aspect ratio of 1.5 or more, and thus, more stress may occur on the short side of the lower surface 100b of the first substrate 100 than occurs on the long side of the lower surface 100b of the substrate 100.

However, in the semiconductor package 2 according to one or more example embodiments, among the plurality of dummy balls 180 provided at each of the first, second, third and fourth corners C1, C2, C3, and C4 of the lower surface 100b of the first substrate 100, a greater number of dummy balls 180 are provided on the short side than the long side of the lower surface 100b of the first substrate 100, and thus, stress applied to the lower surface of the first substrate 100 may be more efficiently distributed toward the dummy balls 180.

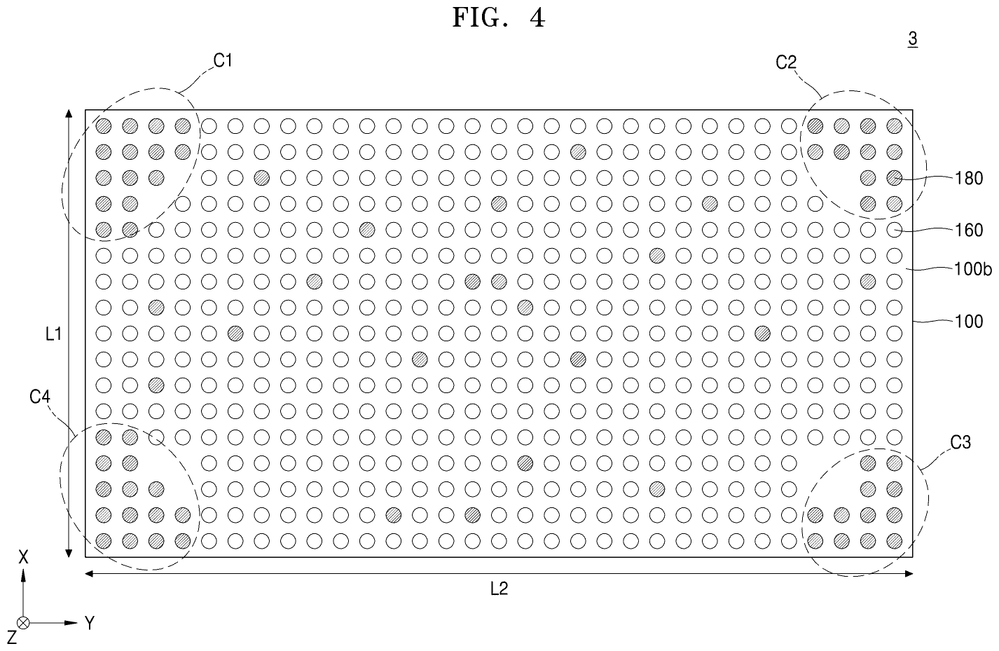

FIG. 4 is a schematic cross-sectional view taken along line A1-A1′ of the semiconductor package 1 of FIG. 1, according to one or more example embodiments. Hereinafter, in describing a semiconductor package 3 of FIG. 4, according to one or more example embodiments, duplicate descriptions previously given with respect to the semiconductor packages 1 and 2 with reference to one or more example embodiments shown in FIGS. 2 and 3 will be omitted, and the mainly differences will be explained.

Referring to FIG. 4, the semiconductor package 3 may include a first bump 160 and a dummy ball 180 provided on the lower surface 100b of the first substrate 100. A plurality of first bumps 160 and dummy balls 180 may be provided on the semiconductor package 3.

A plurality of dummy balls 180 may be provided at each of four corners C1, C2, C3, and C4 of the lower surface 100b of the first substrate 100. The four corners C1, C2, C3, and C4 of the lower surface 100b of the first substrate 100 may be represented as a second corner C2, a third corner C3, and a fourth corner C4 in a clockwise direction based on a first corner C1 at the upper left corner, as shown in FIG. 4.

According to one or more example embodiments, the plurality of dummy balls 180 provided in the first, second, third and fourth corners C1, C2, C3, and C4 may be symmetrically arranged in a first horizontal direction (X). For example, the dummy balls 180 arranged at the first corner C1 and the dummy balls 180 arranged at the fourth corner C4, which is spaced apart from the first corner C1 in the first horizontal direction (X), may be provided symmetrical to each other in the first horizontal direction (X). In addition, the dummy balls 180 arranged at the second corner C2 and the dummy balls 180 arranged at the third corner C3, which is spaced apart from the second corner C2 in the first horizontal direction (X), may be provided symmetrical to each other in the first horizontal direction (X). On the other hand, the dummy balls 180 arranged at the first corner C1 and the dummy balls 180 arranged at the second corner C2, which is spaced apart from the first corner C1 in a second horizontal direction (Y), may be provided asymmetrical with respect to the second horizontal direction (Y). Likewise, the dummy balls 180 arranged at the fourth corner C4 and the dummy balls 180 arranged at the third corner C3, which is spaced apart from the fourth corner C4 in the second horizontal direction (Y), may be provided asymmetrical with respect to the second horizontal direction (Y).

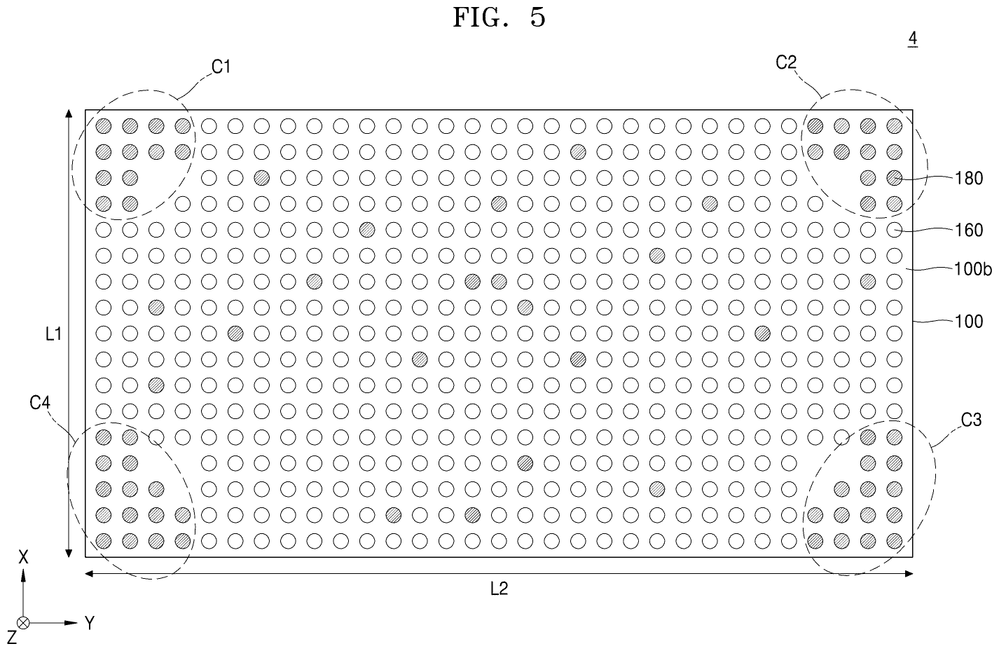

FIG. 5 is a schematic cross-sectional view taken along line A1-A1′ of the semiconductor package 1 of FIG. 1, according to one or more example embodiments. Hereinafter, in describing a semiconductor package 4 of FIG. 5, according to one or more example embodiments, duplicate descriptions previously given with respect to the semiconductor packages 1, 2, and 3 with reference to one or more example embodiments shown in FIGS. 2, 3, and 4 will be omitted, and mainly the differences will be explained.

Referring to FIG. 5, the semiconductor package 4 may include a first bump 160 and a dummy ball 180 provided on the lower surface 100b of the first substrate 100. A plurality of first bumps 160 and dummy balls 180 may be provided on the semiconductor package 4.

A plurality of dummy balls 180 may be provided at each of four corners C1, C2, C3, and C4 of the lower surface 100b of the first substrate 100. The four corners C1, C2, C3, and C4 of the lower surface 100b of the first substrate 100 may be represented as a second corner C2, a third corner C3, and a fourth corner C4 in a clockwise direction relative to a first corner C1 at the upper left corner, as shown in FIG. 5.

According to one or more example embodiments, the plurality of dummy balls 180 provided in the first, second, third and fourth corners C1, C2, C3, and C4 may be symmetrically arranged in the second horizontal direction Y. For example, the dummy balls 180 arranged at the first corner C1 and the dummy balls 180 arranged at the second corner C2, which is spaced apart from the first corner C1 in the second horizontal direction Y, may be symmetrical to each other in the second horizontal direction Y. In addition, the dummy balls 180 arranged at the fourth corner C4 and the dummy balls 180 arranged at the third corner C3, which is spaced apart from the fourth corner C4 in the first horizontal direction X, may be symmetrical to each other in the second horizontal direction Y. On the other hand, the dummy balls 180 arranged at the first corner C1 and the dummy balls 180 arranged at the fourth corner C4, which is spaced apart from the first corner C1 in the first horizontal direction X, may be asymmetrical to each other in the first horizontal direction X. Likewise, the dummy balls 180 arranged at the second corner C2 and the dummy balls 180 arranged at the third corner C3, which is spaced apart from the second corner C2 in the first horizontal direction X, may be asymmetrical to each other in the first horizontal direction X.

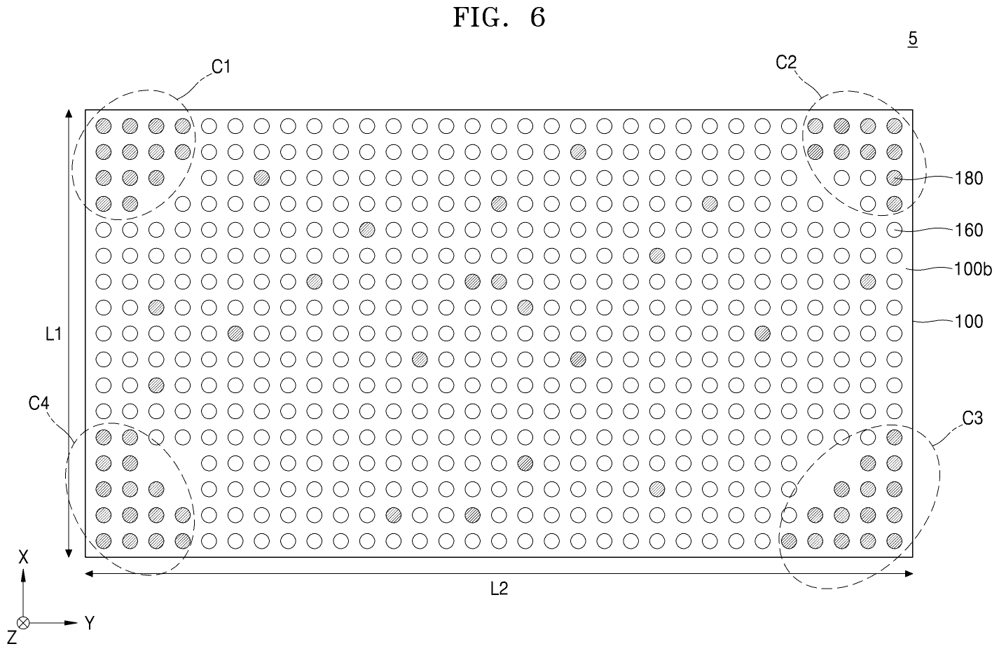

FIG. 6 is a schematic cross-sectional view taken along line A1-A1′ of the semiconductor package 1 of FIG. 1. Hereinafter, in describing a semiconductor package 5 of FIG. 6, according to one or more example embodiments, duplicate descriptions previously given with respect to the semiconductor packages 1, 2, 3, and 4 with reference to one or more example embodiments shown in FIGS. 2, 3, 4, and 5 will be omitted, and mainly the differences will be explained.

Referring to FIG. 6, the semiconductor package 5 may include a first bump 160 and a dummy ball 180 provided on the lower surface 100b of the first substrate 100. A plurality of first bumps 160 and dummy balls 180 may be provided on the semiconductor package 5.

The plurality of dummy balls 180 may be provided at each of four corners C1, C2, C3, and C4 of the lower surface 100b of the first substrate 100. The four corners C1, C2, C3, and C4 of the lower surface 100b of the first substrate 100 may be represented as a second corner C2, a third corner C3, and a fourth corner C4 in a clockwise direction relative to a first corner C1 at the upper left corner, as shown in FIG. 6.

According to one or more example embodiments, the plurality of dummy balls 180 provided in the first, second, third and fourth corners C1, C2, C3, and C4 may each have different arrangements. For example, the arrangement of the dummy balls 180 provided at the first corner C1 may be different from the arrangement of the dummy balls 180 provided at each of the second, third and fourth corners C2, C3, and C4, the arrangement of the dummy balls 180 provided at the second corner C2 may be different from the arrangement of the dummy balls 180 provided at each of the first corner C1, the third corner C3, and the fourth corner C4, the arrangement of the dummy balls 180 provided at the third corner C3 may be different from the arrangement of the dummy balls 180 provided at each of the first corner C1, the second corner C2, and the fourth corner C4, and the arrangement of the dummy balls 180 provided at the fourth corner C4 may be different from the arrangement of the dummy balls 180 provided at each of the first, second, and third corners C1, C2, and C3. Accordingly, the dummy balls 180 provided at the first, second, third and fourth corners C1, C2, C3, and C4 may be asymmetrical in the first horizontal direction X and the second horizontal direction Y.

Because the arrangement of the dummy balls 180 provided at each of the first, second, third and fourth corners C1, C2, C3, and C4 is different, even if uneven stress occurs on the lower surface 100b of the first substrate 100, the stress may be more efficiently distributed to the dummy balls 180.

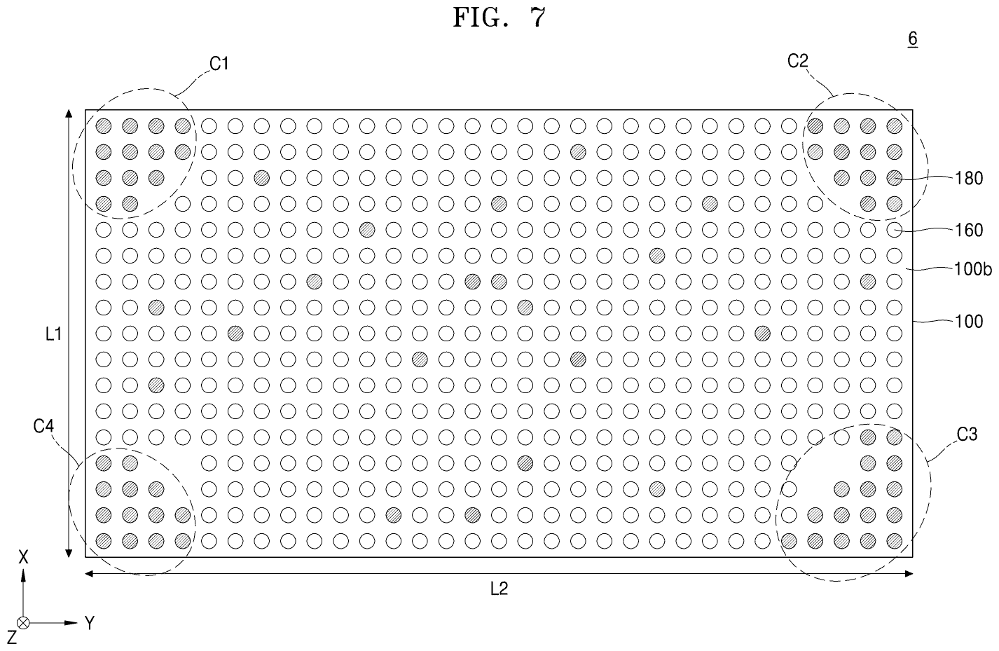

FIG. 7 is a schematic cross-sectional view taken along line A1-A1′ of the semiconductor package 1 of FIG. 1, according to one or more example embodiments. Hereinafter, in describing a semiconductor package 6 of FIG. 7, according to one or more example embodiments, duplicate descriptions previously given with respect to the semiconductor packages 1, 2, 3, 4, and 5 with reference to one or more example embodiments shown in FIGS. 2, 3, 4, 5, and 6 will be omitted, and mainly the differences will be explained.

Referring to FIG. 7, the semiconductor package 6 may include a first bump 160 and a dummy ball 180 provided on the lower surface 100b of the first substrate 100. A plurality of first bumps 160 and dummy balls 180 may be provided on the semiconductor package 6.

A plurality of dummy balls 180 may be provided at each of four corners C1, C2, C3, and C4 of the lower surface 100b of the first substrate 100. The four corners C1, C2, C3, and C4 of the lower surface 100b of the first substrate 100 may be represented as a second corner C2, a third corner C3, and a fourth corner C4 in a clockwise direction relative to a first corner C1 at the upper left corner, as shown in FIG. 7.

According to one or more example embodiments, the arrangement of the dummy balls 180 provided at three corners among the plurality of dummy balls 180 arranged in the first, second, third and fourth corners C1, C2, C3, and C4 may be substantially the same, and the arrangement of the dummy balls 180 provided in one remaining corner may be different from the arrangement of the dummy balls 180 provided in the three corners. For example, with reference to FIG. 7, the arrangements of the dummy balls 180 provided at each of the first corner C1, the second corner C2, and the fourth corner C4 may be substantially the same. For example, the dummy balls 180 provided at the first corner C1 may be symmetrical with the dummy balls 180 provided at the second corner C2 in the second horizontal direction Y. In addition, the dummy balls 180 provided at the first corner C1 may be symmetrical with the dummy balls 180 provided at the fourth corner C4 in the first horizontal direction X. However, the arrangement of the dummy balls 180 provided at the third corner C3 may be different from the arrangement of the dummy balls 180 provided at each of the first corner C1, the second corner C2, and the third corner C3. For example, a greater number of dummy balls 180 may be provided at the third corner C3, or the dummy balls 180 may be arranged longer in one direction.

In FIG. 7, three corners having the same arrangement are shown as the first, second, and fourth corners C1, C2, and C4, and one corner having a different arrangement is shown as the third corner C3, but one or more example embodiments are not limited thereto, and, according to one or more example embodiments, one corner with a different arrangement may be any one of the first corner C1, the second corner C2, the third corner C3, and the fourth corner C4.

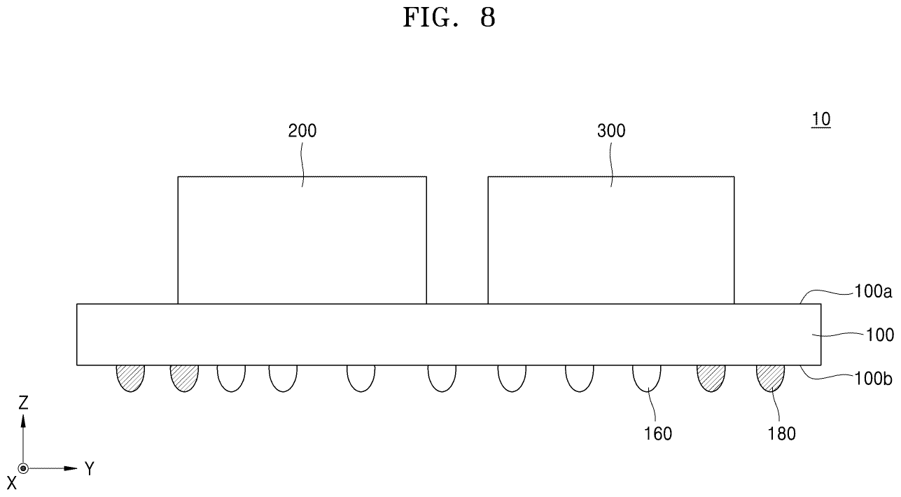

FIG. 8 is a schematic cross-sectional view of a semiconductor package on the Y-Z plane, according to one or more example embodiments. In describing a semiconductor package 10 of FIG. 8, according to one or more example embodiments, duplicate descriptions previously given with respect to the semiconductor packages 1, 2, 3, 4, 5, and 6 with reference to one or more example embodiments shown in FIGS. 2, 3, 4, 5, 6 and 7 will be omitted, and mainly the differences will be explained.

Referring to FIG. 8, the semiconductor package 10 may include a first substrate 100, a first chip 200, and a second chip 300. The first substrate 100 may have an upper surface 100a and a lower surface 100b opposite to the upper surface 100a. The first chip 200 and the second chip 300 may be mounted on the upper surface 100a of the first substrate 100. The first chip 200 and the second chip 300 may be arranged to be spaced apart from each other by a predetermined distance.

The first substrate 100 may be electrically connected to each of the first chip 200 and the second chip 300. A first bump 160 and a dummy ball 180 may be provided on the lower surface 100b of the first substrate 100. A plurality of first bumps 160 and dummy balls 180 may be provided. The first substrate 100 may be connected to an external device, such as a motherboard, using the first bump 160.

According to one or more example embodiments, the dummy balls 180 may be arranged at the four corners of the lower surface 100b of the first substrate 100, according to one or more example embodiments, as shown in FIGS. 2, 3, 4, 5, 6 and 7.

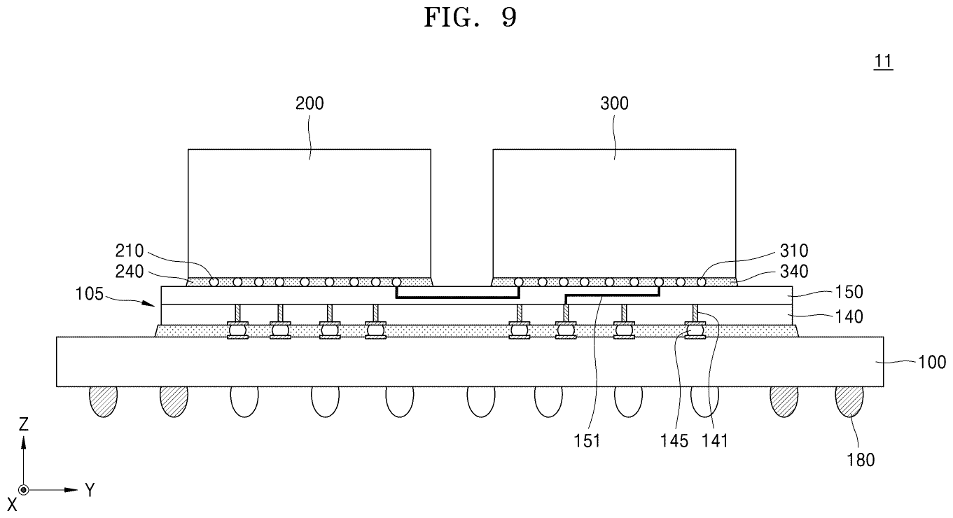

FIG. 9 is a schematic cross-sectional view of the semiconductor package 10 of FIG. 8 on the Y-Z plane. Hereinafter, in describing a semiconductor package 11 of FIG. 9, according to one or more example embodiments, duplicate descriptions previously given with respect to the semiconductor package 8 with reference to one or more example embodiments shown in FIG. 8 will be omitted, and mainly the differences will be explained.

Referring to FIG. 9, the semiconductor package 11 may further include an interposer substrate 105 that electrically connects the first chip 200 to the second chip 300. The interposer substrate 105 may be formed using silicon. The interposer substrate 105 may include a wiring layer 150 in which a wiring pattern 151 for electrically connecting the first chip 200 and the second chip 300 is provided and a body layer 140 in which a through electrode 141 is formed. The wiring pattern 151 may electrically connect the first chip 200 to the second chip 300, or may electrically connect the first chip 200 and the through electrode 141 and may connect the second chip 300 and the through electrodes 141. The through electrodes 141 may penetrate the body layer 140 in a vertical direction Z. The through electrodes 141 may be electrically connected to a second bump 145 using a pad formed on a lower surface of the body layer 140.

According to one or more example embodiments, the first chip 200 may be mounted on the interposer substrate 105 using a first chip connection bump 210. A first underfill material layer 240 may be provided between the first chip 200 and the interposer substrate 105. The second chip 300 may be mounted on the interposer substrate 105 using the second chip connection bump 310. A second underfill material layer 340 may be provided between the second chip 300 and the interposer substrate 105.

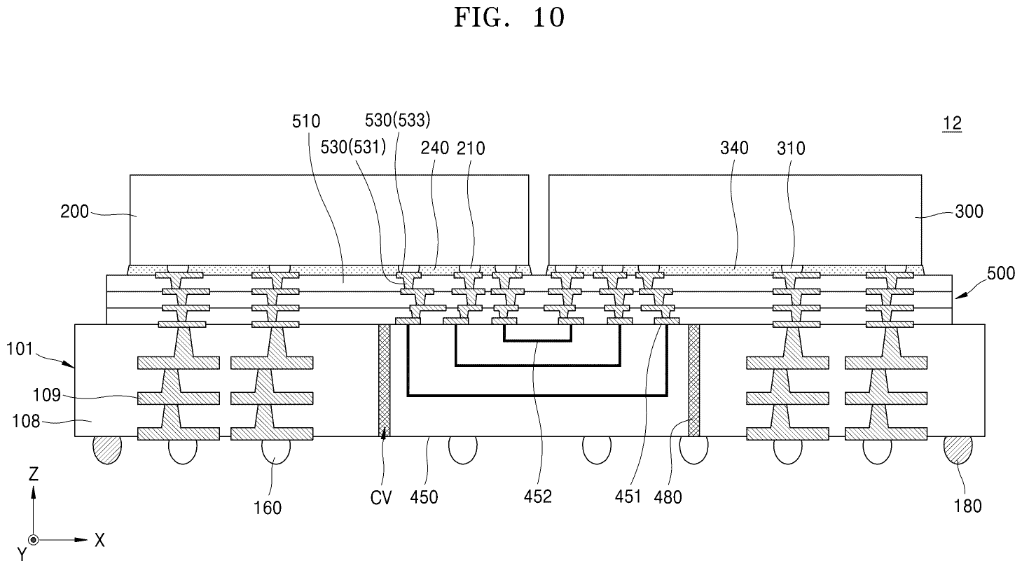

FIG. 10 is a schematic cross-sectional view of the semiconductor package 10 of FIG. 8 on the Y-Z plane, according to one or more example embodiments. Hereinafter, in describing a semiconductor package 12 of FIG. 10, according to one or more example embodiments, duplicate descriptions previously given with respect to the semiconductor packages 10 and 11 with reference to one or more example embodiments shown in FIGS. 8 and 9 will be omitted, and mainly the differences will be explained.

Referring to FIG. 10, the semiconductor package 12 may include a first substrate 101, a third substrate 500, a first chip 200, a second chip 300, and a bridge chip 450. The first substrate 101 may include a body 108 and a cavity CV penetrating the body 108 in the vertical direction Z. A wiring pattern 109 may be provided inside the body 108. The bridge chip 450 may be provided inside the cavity CV. The adhesive portion 480 may fix the bridge chip 450 provided inside the cavity CV. The adhesive portion 480 may be provided between the bridge chip 450 and the body 108.

The third substrate 500 may include a redistribution insulating layer 510 and a redistribution pattern 530. The redistribution pattern 530 may include a redistribution via pattern 531 and a redistribution line pattern 533. A plurality of redistribution insulating layers 510 may be provided by being stacked on each other in the vertical direction Z. The redistribution insulating layers 510 may be formed from, for example, a PID or PSPI. The redistribution pattern 530 may be provided within the redistribution insulating layer 510. The redistribution pattern 530 may be formed to penetrate the redistribution insulating layers 510 from top to bottom of the third substrate 500. Accordingly, the redistribution pattern 530 may perform dynamics of an electrical connection path penetrating upper and lower surfaces of the third substrate 500. That is, the redistribution pattern 530 may electrically connect each of the first chip 200 and the second chip 300 to the wiring pattern 109 of the first substrate 101. Also, the redistribution pattern 530 may electrically connect each of the first chip 200 and the second chip 300 to the bridge chip 450.

The redistribution pattern 530 may include a redistribution line pattern 533 and a redistribution via pattern 531. The redistribution pattern 530 may have a multi-layer structure in which redistribution line patterns 533 and redistribution via patterns 531 are alternately stacked.

The redistribution line pattern 533 may have a shape extending in the horizontal direction along at least one of upper and lower surfaces of each of the redistribution insulating layers 510. The redistribution via pattern 531 may have a shape that extends through the redistribution insulating layer 510 in the vertical direction Z. The redistribution via pattern 531 may electrically connect the upper redistribution line patterns 533 located at different levels in the vertical direction Z. In one or more example embodiments, at least some of the redistribution line patterns 533 may be formed together with some of the redistribution via patterns 531 to form one body.

The bridge chip 450 may include a bridge circuit 452 and a bridge pad 451. The bridge chip 450 may connect the first chip 200 to the second chip 300. The bridge circuit 452 may electrically connect the redistribution pattern 530 electrically connected to the first chip 200 and the redistribution pattern 530 electrically connected to the second chip 300. The bridge pad 451 may be provided on an upper surface of the bridge chip 450 and may be electrically connected to the redistribution pattern 530 and the bridge circuit 452.

A first bump 160 and a dummy ball 180 may be provided on a lower surface of the first substrate 101. A plurality of first bumps 160 and dummy balls 180 may be provided.

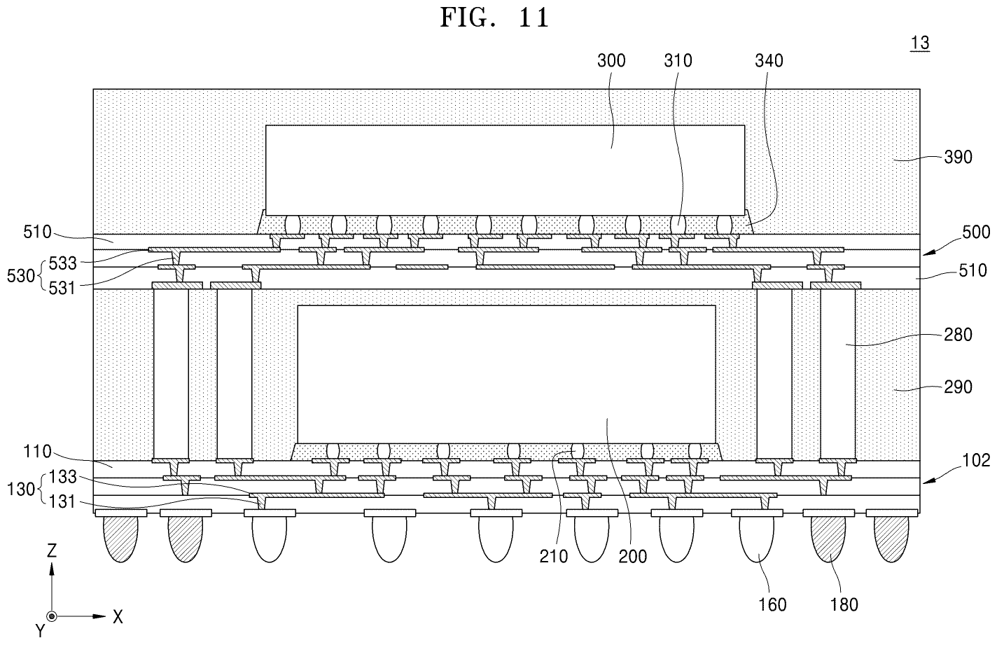

FIG. 11 is a schematic cross-sectional view of a semiconductor package 13 on the Y-Z plane, according to one or more example embodiments. Hereinafter, in describing a semiconductor package 13 of FIG. 11, according to one or more example embodiments, duplicate descriptions previously given with respect to the semiconductor package 1, 2, 3, 4, 5, and 6 with reference to one or more example embodiments shown in FIGS. 1, 2, 3, 4, 5, 6 and 7 will be omitted, and mainly the differences will be explained.

Referring to FIG. 11, the semiconductor package 13 includes a first substrate 102, a first chip 200, a first molding member 290, a conductive pillar 280, a third substrate 500, a second chip 300, and a second molding member 390.

According to one or more example embodiments, the first substrate 102 may be a redistribution structure formed using a redistribution process and may include a first redistribution insulating layer 110 and a first redistribution pattern 130. The first redistribution insulating layer 110 may be provided as a plurality of layers stacked in one direction, and the first redistribution pattern 130 may include a plurality of patterns provided in the stacked insulating layers. The first redistribution pattern 130 may be electrically connected to each of the conductive pillars 280 and the first chip 200. The first molding member 290 may be provided to surround the first chip 200. The first molding member 290 may include a thermosetting resin, such as an epoxy resin, a thermoplastic resin, such as polyimide, or a resin including a reinforcing material, such as an inorganic filler, and more specifically, may include Ajinomoto Build-up Film (ABF), FR-4, BT, etc., but one or more example embodiments are not limited thereto, and the first molding member 290 may include a molding material, such as EMC or a photosensitive material, such as photoimagable encapsulant (PIE). In one or more example embodiments, a portion of the first molding member 290 may include an insulating material, such as a silicon oxide film, a silicon nitride film, or a silicon oxynitride film.

The conductive pillar 280 may be formed by penetrating the first molding member 290 in the vertical direction Z. The conductive pillar 280 may have a shape extending in the vertical direction Z. The conductive pillar 280 may include, for example, a through mold via or a conductive post. The conductive pillar 280 may include, for example, copper (Cu).

The third substrate 500 may be provided on an upper surface of the first molding member 290. The third substrate 500 may include an upper surface and a lower surface that are opposite to each other, and at least one of the upper surface and the lower surface may be flat. The third substrate 500 may electrically connect the conductive pillar 280 and the second chip 300. The third substrate 500 may include a second redistribution pattern 530 to a second redistribution insulating layer 510. The third substrate 500 may electrically connect the conductive pillar 280 to the second chip 300 using the second redistribution pattern 530. The second redistribution insulating layer 510 may be provided as a plurality of layers stacked in the vertical direction Z. The second redistribution pattern 530 may include a second redistribution via pattern 531 and a second redistribution line pattern 533.

The second chip 300 may be mounted on an upper surface of the third substrate 500. The second chip 300 may be mounted on the upper surface of the third substrate 500 using the second chip connection bump 310 using a flip chip method.

The second molding member 390 may surround the second chip 300 on the upper surface of the third substrate 500. Because the second molding member 390 is substantially the same as or similar to the first molding member 290, duplicate description of the second molding member 390 will be omitted.

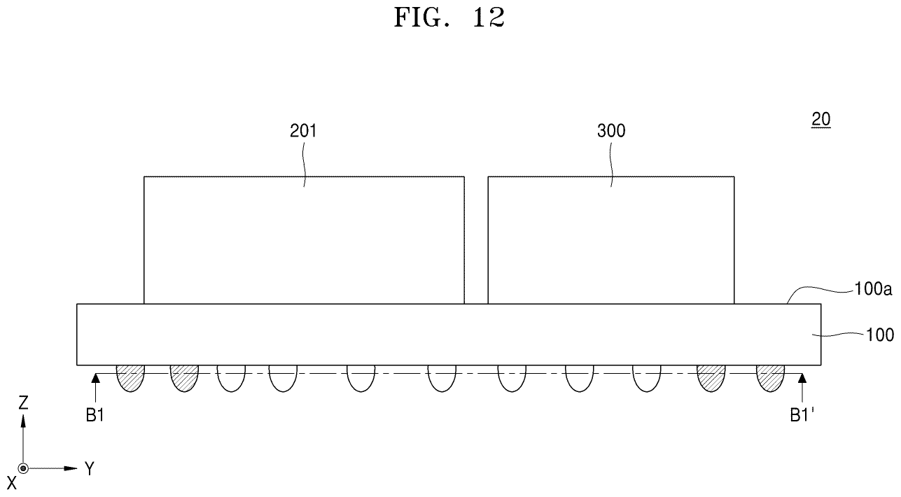

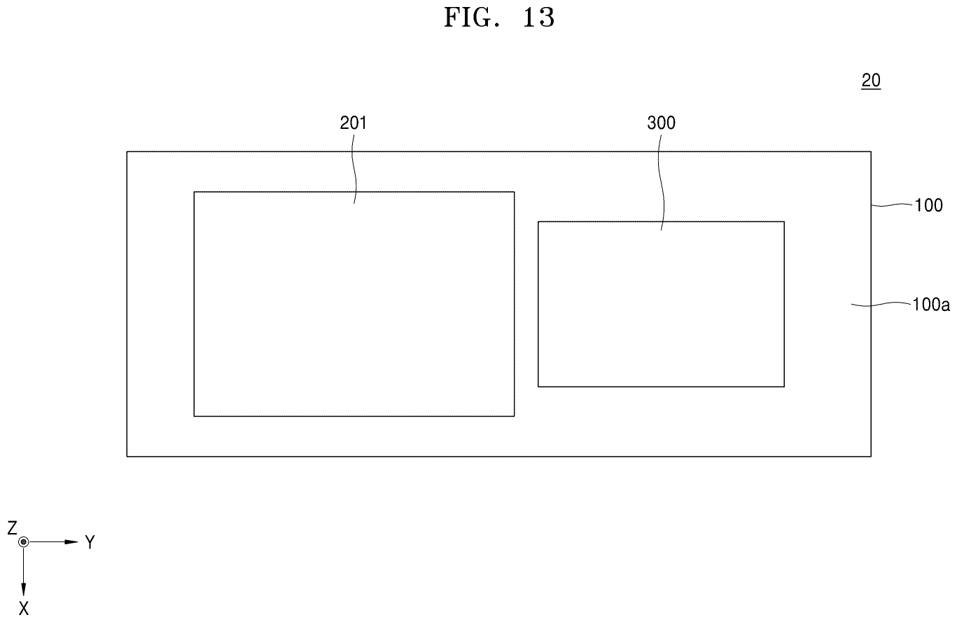

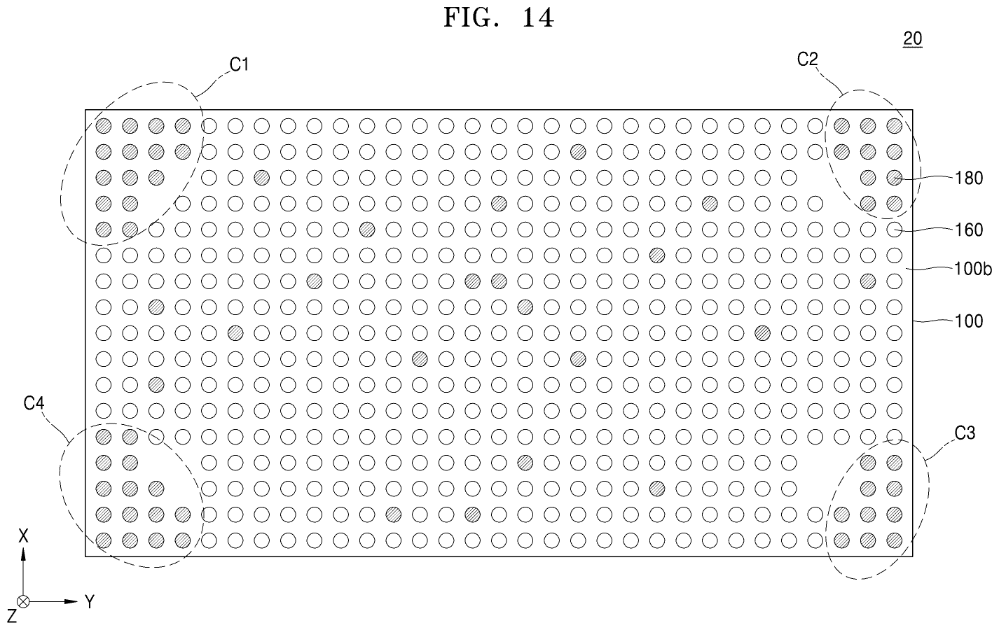

FIG. 12 is a schematic cross-sectional view of a semiconductor package 20 on the Y-Z plane, according to one or more example embodiments. FIG. 13 is a schematic plan view of the semiconductor package 20 of FIG. 12. FIG. 14 is a cross-sectional view taken along line B1-B1′ of the semiconductor package 20 of FIG. 12, according to one or more example embodiments. Hereinafter, in describing a semiconductor package 20 of FIG. 12, according to one or more example embodiments, duplicate descriptions previously given with respect to the semiconductor package 10 with reference to one or more example embodiments shown in FIG. 8 will be omitted, and mainly the differences will be explained.

Referring to FIGS. 12, 13 and 14, the semiconductor package 20 may include a first substrate 100, a first chip 201, and a second chip 300. The first substrate 100 may have an upper surface 100a and a lower surface 100b opposite to the upper surface 100a. The first chip 201 and the second chip 300 may be mounted on the upper surface 100a of the first substrate 100. The first chip 201 and the second chip 300 may be arranged to be spaced apart from each other by a predetermined distance.

A first bump 160 and a dummy ball 180 may be provided on the lower surface 100b of the first substrate 100. A plurality of dummy balls 180 may be provided at four corners C1, C2, C3, and C4 of the lower surface 100b of the first substrate 100. The four corners C1, C2, C3, and C4 of the lower surface 100b of the first substrate 100 may be represented as a second corner C2, a third corner C3, and a fourth corner C4 in a clockwise direction relative to a first corner C1 at the upper left corner, as shown in FIG. 14.

The number of dummy balls 180 provided at each of two corners adjacent to the first chip 201, for example, the first corner C1 and the fourth corner C4 among the first, second, third and fourth corners C1, C2, C3, and C4 of the lower surface 100b of the first substrate 100, may be greater than the number of dummy balls 180 provided at each of two corners adjacent to the second chip 300, for example, the second corner C2 and the third corner C3 among the first, second, third and fourth corners C1, C2, C3, and C4 of the lower surface 100b of the first substrate 100.

According to one or more example embodiments, the first chip 201 and the second chip 300 may have different sizes. For example, the first chip 201 may have a greater cross-section on the X-Y plane than the second chip 300. According to one or more example embodiments, a footprint of the first chip 201 may be greater than a footprint of the second chip 300. According to one or more example embodiments, a weight of the first chip 201 may be greater than a weight of the second chip 300.

In the semiconductor package 20 according to one or more example embodiments, because the weight or size of the first chip 201 is greater than that of the second chip 300, more stress may occur at the two corners of the lower surface 100b of the first substrate 100 adjacent to the first chip 201. In this case, more dummy balls 180 may be arranged at the two corners of the lower surface 100b of the first substrate 100 adjacent to the first chip 201, more specifically, in each of the first corner C1 and the fourth corner C4, than in the second corner C2 and the third corner C3, and thus, the stress occurring within the semiconductor package 20 may be more efficiently distributed to the dummy balls 180.

While example embodiments have been particularly shown and described, it will be apparent to those skilled in the art that various changes in form and details may be made therein without departing from the spirit and scope of the following claims.

What is claimed is:

1. A semiconductor package comprising:
a first substrate having a rectangular cross-section on an X-Y plane, wherein the first substrate comprises an upper surface and a lower surface opposite to the upper surface, and an aspect ratio of the rectangular cross-section is in a range of 1.5 to 2.2;
a first chip on the upper surface of the first substrate; and
a plurality of dummy balls on each of four corner areas of the lower surface of the first substrate.

2. The semiconductor package of claim 1, wherein a number of the plurality of dummy balls on each of the four corner areas of the lower surface of the first substrate is in a range of 8 to 16.

3. The semiconductor package of claim 1, wherein, among the plurality of dummy balls on each of the four corner areas, more of the plurality of dummy balls are provided adjacent to a shorter side of the lower surface of the first substrate than are provided adjacent to a longer side of the lower surface of the first substrate.

4. The semiconductor package of claim 1, wherein the plurality of dummy balls on each of the four corner areas are arranged symmetrically in an X-axis direction.

5. The semiconductor package of claim 1, wherein the plurality of dummy balls on each of the four corner areas are arranged symmetrically in a Y-axis direction.

6. The semiconductor package of claim 1, wherein the plurality of dummy balls have different arrangements in each of the four corner areas.

7. The semiconductor package of claim 1, wherein the plurality of dummy balls have a same arrangement in any three corner areas, from among the four corner areas, and a different arrangement in a remaining corner area, from among the four corner areas.

8. The semiconductor package of claim 1, wherein each of the plurality of dummy balls is disconnected from a wiring provided in the first substrate.

9. The semiconductor package of claim 1, further comprising:
a second chip on the upper surface of the first substrate and spaced apart from the first chip in a Y-axis direction.

10. The semiconductor package of claim 9, wherein a footprint of the first chip on the X-Y plane is greater than a footprint of the second chip on the X-Y plane, and
wherein more of the plurality of dummy balls are on two corner areas, from among the four corner areas, which are adjacent to the first chip, than are provided on two corner areas, from among the four corner areas, which are adjacent to the second chip.

11. The semiconductor package of claim 1, further comprising:
a first molding member surrounding the first chip;
a conductive pillar penetrating the first molding member in a Z-axis direction;
a third substrate on the first molding member;
a second chip on the third substrate; and
a second molding member surrounding the second chip.

12. A semiconductor package comprising:
a first substrate having a rectangular cross-section on an X-Y plane, wherein the first substrate comprises an upper surface and a lower surface opposite to the upper surface, and an aspect ratio of the rectangular cross-section is in a range of 1.5 to 2.2;
a first chip on the upper surface of the first substrate;
a second chip on the upper surface of the first substrate and spaced apart from the first chip in a Y-axis direction; and
a plurality of dummy balls on each of four corner areas of the lower surface of the first substrate,
wherein a footprint of the first substrate is greater than a sum of a footprint of the first chip and a footprint of the second chip.

13. The semiconductor package of claim 12, wherein, among the plurality of dummy balls on each of the four corner areas, more of the plurality of dummy balls are adjacent to a shorter side of the lower surface of the first substrate than are adjacent to a longer side of the lower surface of the first substrate.

14. The semiconductor package of claim 12, further comprising:
a wiring pattern electrically connecting the first chip to the second chip;
a through electrode electrically connecting the wiring pattern to the first substrate; and
an interposer substrate on the upper surface of the first substrate.

15. The semiconductor package of claim 12, further comprising:
a bridge chip in a cavity penetrating the first substrate in a Z-axis direction; and
a third substrate on the first substrate.

16. The semiconductor package of claim 12, wherein an arrangement of the plurality of dummy balls is different in each of the four corner areas.

17. The semiconductor package of claim 12, wherein a footprint of the first chip on the X-Y plane is greater than a footprint of the second chip on the X-Y plane, and
wherein more of the plurality of dummy balls are on two corner areas, from among the four corner areas, which are adjacent to the first chip, than are provided on two corner areas, from among the four corner areas, which are adjacent to the second chip.

18. A semiconductor package comprising:
a first substrate having a rectangular cross-section along an X-Y plane, wherein the first substrate comprises an upper surface and a lower surface opposite to the upper surface, and an aspect ratio of the rectangular cross-section is in a range of 1.5 to 2.2;
a first chip on the upper surface of the first substrate;
a second chip on the upper surface of the first substrate and spaced apart from the first chip in a Y-axis direction;
a plurality of dummy balls on each of four corner areas of the lower surface of the first substrate; and
a plurality of first bumps on the lower surface of the first substrate,
wherein a length of a shorter side of the rectangular cross-section is in a range of 8 mm to 12 mm,
wherein a number of the plurality of dummy balls on each of the four corner areas is in a range of 8 to 16,
wherein each of the plurality of dummy balls is electrically disconnected from a wiring provided in the first substrate, and
wherein the plurality of dummy balls have different arrangements in at least two corner areas from among the four corner areas.

19. The semiconductor package of claim 18, wherein, among the plurality of dummy balls on each of the four corner areas, more of the plurality of dummy balls are adjacent to a shorter side of the lower surface of the first substrate than are adjacent to a longer side of the lower surface of the first substrate.

20. The semiconductor package of claim 18, wherein a footprint of the first chip on the X-Y plane is greater than a footprint of the second chip on the X-Y plane, and
wherein more of the plurality of dummy balls are on two corner areas, from among the four corner areas, which are adjacent to the first chip, than on two corner areas, from among the four corner areas, which are adjacent to the second chip.
